(19) United States
(12) Patent Application Publication
(10) Pub. No.: US 2024/0251682 A1
(43) Pub. Date: Jul. 25, 2024

(54) COMPOSITE SUBSTRATE AND METHOD FOR PRODUCING COMPOSITE SUBSTRATE

(71) Applicant: NGK INSULATORS, LTD., Nagoya-shi (JP)

(72) Inventors: Yudai UNO, Nagoya-shi (JP); Tomoyoshi TAI, Inazawa-shi (JP); Masahiko NAMERIKAWA, Seto-shi (JP)

(21) Appl. No.: 18/586,617

(22) Filed: Feb. 26, 2024

Related U.S. Application Data
(63) Continuation of application No. PCT/JP2022/030873, filed on Aug. 15, 2022.

(30) Foreign Application Priority Data
Aug. 27, 2021 (JP) 2021-139135

(51) Int. Cl. H10N 30/00; H10N 30/072; H10N 30/097; H10N 30/853; H10N 30/87

(52) U.S. Cl. CPC H10N 30/10513; H10N 30/072; H10N 30/097; H10N 30/8554; H10N 30/87

(57) ABSTRACT

A composite substrate includes: a support substrate; a piezoelectric film arranged above the support substrate; and a joining layer arranged between the support substrate and the piezoelectric film, wherein the piezoelectric film includes a polycrystalline substance having a degree of c-axis orientation determined by a Lotgering method of 80% or less, and wherein the joining layer includes an amorphous substance.

### CROSS-REFERENCE TO RELATED APPLICATIONS

This application is a continuation under 35 U.S.C. 120 of International Application PCT/JP2022/030873 having the International Filing Date of Aug. 15, 2022, and having the benefit of the earlier filing date of Japanese Application No. 2021-139135, filed on Aug. 27, 2021. Each of the identified applications is fully incorporated herein by reference.

### BACKGROUND OF THE INVENTION

### Technical Field

The present invention relates to a composite substrate and a method of producing a composite substrate.

### Background Art

A piezoelectric actuator that vibrates an electro-mechanical conversion film has been put into practical use in a liquid droplet ejection head of an ink jet recording apparatus. In recent years, the piezoelectric actuator has been expected to be applied to other uses (e.g., a MEMS mirror device for a head-up display). In a piezoelectric element used in the piezoelectric actuator, for example, as disclosed in Patent Literature 1, there is used a composite substrate including a lower electrode formed on a substrate, a piezoelectric layer formed on the lower electrode, and an upper electrode formed on the piezoelectric layer. As another example, as disclosed in Patent Literature 2, there is used a piezoelectric element in which a piezoelectric body including an upper electrode and a lower electrode, and a support substrate are joined to each other via an adhesive.

### CITATION LIST

### Patent Literature

[PTL 1] WO 2017/043383 A1
[PTL 2] JP 5525351 B2

### SUMMARY OF THE INVENTION

However, when the method disclosed in Patent Literature 1 is used to produce the above-mentioned composite substrate, there is a problem in that a warp is liable to occur. The occurrence of a warp leads to a decrease in yield. Meanwhile, when the method disclosed in Patent Literature 2 is used, although the occurrence of a warp can be suppressed, it is difficult to reduce the thickness of the piezoelectric body, and hence it is difficult to apply such method to, for example, a low-voltage-driven piezoelectric actuator. In addition, an adhesive (typically, an organic adhesive) is used, and hence there is concern about high-temperature reliability.

The present invention has been made in view of the foregoing, and a primary object of the present invention is to provide a composite substrate in which the occurrence of a warp is suppressed.

1. According to one embodiment of the present invention, there is provided a composite substrate, including: a support substrate; and a piezoelectric film arranged above the support substrate, wherein the piezoelectric film includes a polycrystalline substance having a degree of c-axis orientation determined by a Lotgering method of 80% or less.

2. The composite substrate according to the above-mentioned item 1 may further include a joining layer arranged between the support substrate and the piezoelectric film. The joining layer may include an amorphous substance.

3. In the composite substrate according to the above-mentioned item 1 or 2, the piezoelectric film may contain a PZT-based compound.

4. In the composite substrate according to any one of the above-mentioned items 1 to 3, the piezoelectric film may contain a ternary PZT.

5. In the composite substrate according to any one of the above-mentioned items 1 to 4, the piezoelectric film may include a sintered body.

6. In the composite substrate according to any one of the above-mentioned items 1 to 5, the piezoelectric film may have a thickness of 0.3 μm or more and 100 μm or less.

7. The composite substrate according to any one of the above-mentioned items 1 to 6 may further include an electrode arranged between the piezoelectric film and the support substrate. The electrode may include a first electrode layer, a second electrode layer, and a third electrode layer, and a material for forming the first electrode layer and a material for forming the third electrode layer may be substantially identical to each other.

8. The composite substrate according to any one of the above-mentioned items 1 to 7 may further include an electrode arranged between the piezoelectric film and the support substrate. The electrode may include an amorphous substance.

9. The composite substrate according to any one of the above-mentioned items 1 to 8 may further include an argon-containing amorphous layer, which is arranged between the piezoelectric film and the support substrate, and which contains argon.

10. In the composite substrate according to any one of the above-mentioned items 1 to 9, the support substrate may have an amorphous region formed in an end portion thereof on an upper side, and the amorphous region may have a thickness of from 2 nm to 30 nm.

11. In the composite substrate according to the above-mentioned item 10, the amorphous region may contain argon, and the amorphous region may have an argon concentration of from 0.5 atm % to 30 atm %.

12. The composite substrate according to any one of the above-mentioned items 1 to 11 may have a total thickness variation of 10 μm or less.

13. According to another embodiment of the present invention, there is provided a piezoelectric device, including the composite substrate of any one of the above-mentioned items 1 to 12.

14. According to yet another embodiment of the present invention, there is provided a method of producing a composite substrate, including: preparing a piezoelectric substrate including a sintered body; and joining the piezoelectric substrate and a support substrate to each other.

15. The method of producing a composite substrate according to the above-mentioned item 14 may further include forming a joining layer on the piezoelectric substrate at 300° C. or less.

16. The method of producing a composite substrate according to the above-mentioned item 14 or 15 may further include forming an electrode on the piezoelectric substrate at 300° C. or less.

### Advantageous Effects of Invention

According to the embodiment of the present invention, there can be provided the composite substrate in which the occurrence of a warp is suppressed.

### BRIEF DESCRIPTION OF THE DRAWINGS

FIG. 1 is a schematic sectional view for illustrating the schematic configuration of a composite substrate according to a first embodiment of the present invention.

FIG. 2 is a schematic sectional view for illustrating the schematic configuration of a composite substrate according to a second embodiment of the present invention.

FIG. 3 is a schematic sectional view for illustrating the schematic configuration of a composite substrate according to a third embodiment of the present invention.

FIG. 4A is a view for illustrating an example of a production process for a composite substrate according to one embodiment.

FIG. 4B is a view subsequent to FIG. 4A.

FIG. 4C is a view subsequent to FIG. 4B.

FIG. 5A is a cross-sectional TEM observation photograph (magnification: 50,000) of a composite substrate of Example 4.

FIG. 5B is a cross-sectional TEM observation photograph (magnification: 400,000) of the composite substrate of Example 4.

FIG. 5C is a cross-sectional TEM observation photograph (magnification: 2,000,000) of the composite substrate of Example 4.

### DESCRIPTION OF EMBODIMENTS

Embodiments of the present invention are described below with reference to the drawings. However, the present invention is not limited to these embodiments. In addition, in order to further clarify the description, the width, thickness, shape, and the like of each portion may be schematically illustrated in the drawings as compared to the embodiments, but the illustration is merely an example and does not limit the interpretation of the present invention.

### A. Composite Substrate

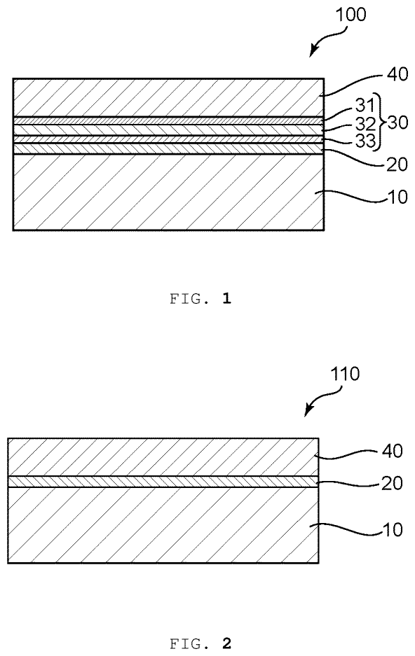

FIG. 1 is a schematic sectional view for illustrating the schematic configuration of a composite substrate according to a first embodiment of the present invention. A composite substrate 100 includes a support substrate 10, a joining layer 20, an electrode (lower electrode) 30, and a piezoelectric film 40 in the stated order. In the illustrated example, the lower electrode 30 includes a first lower electrode layer 31, a second lower electrode layer 32, and a third lower electrode layer 33 in the stated order from the piezoelectric film 40 side.

The composite substrate 100 may further include any appropriate layer (not shown). The kinds, functions, number, combination, arrangement, and the like of such layers may be appropriately set in accordance with purposes. For example, the composite substrate 100 may include an electrode (upper electrode) arranged on the piezoelectric film 40. The composite substrate 100 is typically used as an actuator, and for example, a wiring layer is formed on the upper electrode.

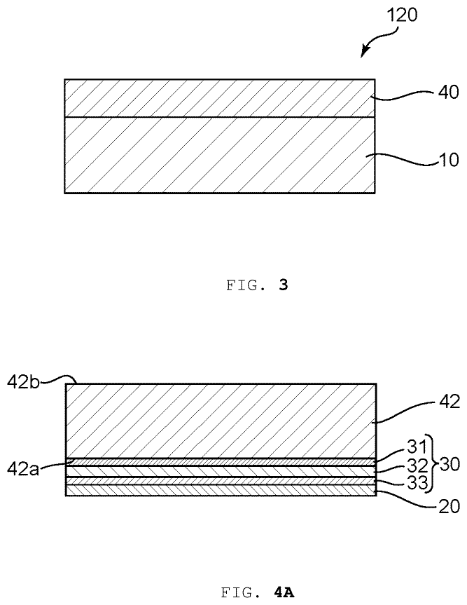

FIG. 2 is a schematic sectional view for illustrating the schematic configuration of a composite substrate according to a second embodiment of the present invention. A composite substrate 110 includes the support substrate 10, the joining layer 20, and the piezoelectric film 40 in the stated order. The second embodiment is different from the first embodiment in that the electrode 30 is arranged between the support substrate 10 (joining layer 20) and the piezoelectric film 40 in the first embodiment, but the electrode 30 is not arranged in the second embodiment. Thus, the composite substrate 110 may include an electrode (upper electrode) arranged on the piezoelectric film 40.

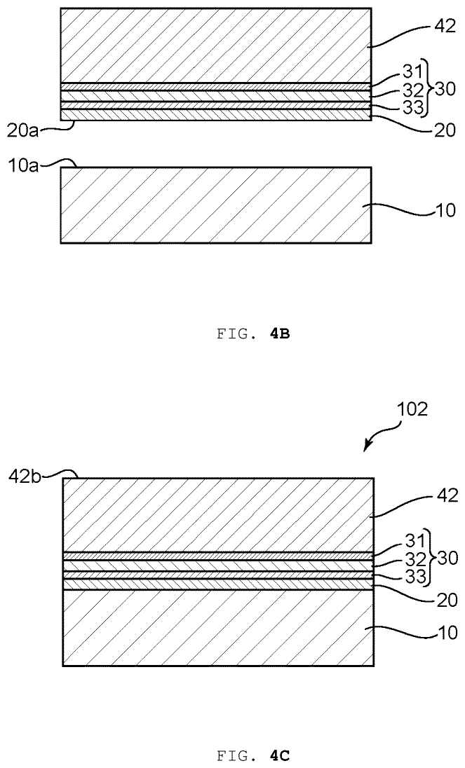

FIG. 3 is a schematic sectional view for illustrating the schematic configuration of a composite substrate according to a third embodiment of the present invention. A composite substrate 120 includes the support substrate 10 and the piezoelectric film 40. The third embodiment is different from the second embodiment in that the joining layer 20 is arranged between the support substrate 10 and the piezoelectric film 40 in the second embodiment, but the joining layer 20 is not arranged in the third embodiment. When the joining layer 20 is omitted, an amorphous region described later may be formed in an end portion of the piezoelectric film 40 on the support substrate 10 side, though the region is not shown.

In one embodiment, in the composite substrate 110, 120, for example, an electrode (lower electrode) may be formed on an exposed surface of the piezoelectric film 40 formed by removing the support substrate 10 and the joining layer 20 through etching or the like.

The composite substrate may be produced in any appropriate shape. In one embodiment, the substrate may be produced in the form of a so-called wafer. The size of the composite substrate may be appropriately set in accordance with purposes. For example, the diameter of the wafer is from 50 mm to 150 mm.

The total thickness variation (TTV) of the composite substrate is preferably 10 μm or less, more preferably 5 μm or less, still more preferably 2 μm or less.

### A-1. Piezoelectric Film

The piezoelectric film includes a polycrystalline substance. The polycrystalline substance is non-oriented. The term “non-oriented” as used herein refers to a degree of c-axis orientation determined by a Lotgering method of 80% or less, preferably 60% or less, more preferably 40% or less, still more preferably 20% or less, particularly preferably 10% or less. The piezoelectric film typically includes a sintered body. For example, a grain boundary is recognized in the piezoelectric film by TEM observation. A composite substrate in which the occurrence of a warp is suppressed can be obtained by adopting such configuration. Specifically, the piezoelectric film can be formed independently, and hence, for example, an internal stress is not generated through an interaction with another member at the time of formation of the piezoelectric film. In addition, when the piezoelectric film includes a non-oriented polycrystalline substance, options for materials for forming the piezoelectric film are increased, and diversified characteristics can be supported. Specifically, characteristics, such as a piezoelectric constant, a dielectric constant, an electro-mechanical coupling coefficient, and a Curie temperature, can be finely adjusted in accordance with needs. Further, when the piezoelectric film includes a non-oriented polycrystalline substance, the piezoelectric film can be formed at low cost, and such configuration can contribute to improving the reliability of a composite substrate to be obtained.

The above-mentioned degree of c-axis orientation determined by a Lotgering method is a degree of (001) plane orientation F₍₀₀₁₎ calculated through use of the following expressions from an XRD profile obtained by measurement with an X-ray diffraction apparatus.

$${F}_{( 001 )} = ( p - {p}_{0} ) / ( 1 - {p}_{0} ) \times 100$$

$$p = \sum I ( 001 ) / \sum I ( hk 1 )$$

$${p}_{0} = \sum {I}_{0} ( 001 ) / \sum {I}_{0} ( hk 1 )$$

(I and I₀ each represent a diffraction intensity, and “p” and p₀ are each calculated from the ratio of diffraction intensities derived from a c-axis diffraction plane (001) to diffraction intensities of all diffraction planes (hkl). I and “p” each represent a value obtained from an XRD profile of the piezoelectric film (piezoelectric substrate), and I₀ and p₀ each represent a value obtained from an XRD profile of a sample obtained by powderizing the piezoelectric film (piezoelectric substrate).

Any appropriate ferroelectric is used as a material for forming the piezoelectric film. A lead zirconate titanate (PZT)-based compound is preferably used. Not only a binary PZT (PbZrO₃—PbTiO₃) of lead titanate and lead zirconate having a perovskite-type structure but also a ternary PZT may be used as the PZT-based compound. When the piezoelectric film includes a non-oriented polycrystalline substance, the piezoelectric film may contain a ternary PZT. Through use of the ternary PZT, a composite substrate (piezoelectric element) to be obtained can be adapted to diversified characteristics. Specifically, characteristics, such as a piezoelectric constant, a dielectric constant, an electro-mechanical coupling coefficient, and a Curie temperature, can be finely adjusted in accordance with needs.

The atomic ratio (Zr/Ti) of Zr to Ti in the piezoelectric film is preferably 0.7 or more and 2.0 or less, more preferably 0.9 or more and 1.5 or less.

The ternary PZT is typically represented by ATiO₃—PbZrO₃—PbTiO₃ or PbBO₃—PbZrO₃—PbTiO₃, where A and B each represent an element except Pb, Zr, and Ti. Examples of the element A in the third component of the ternary PZT include Li, Na, K, Bi, La, Ce, and Nd. Examples of the element B in the third component of the ternary PZT include Li, Cu, Mg, Ni, Zn, Mn, Co, Sn, Fe, Cd, Sb, Al, Yb, In, Sc, Y, Nb, Ta, Bi, W, Te, and Re. Those elements may be used alone or in combination thereof.

The proportion of the third component with respect to the sum of Zr, Ti, Pb, and the third component (element A and/or element B) in the piezoelectric film, specifically, the atomic ratio “third component/(Zr+Ti+Pb+third component)” is preferably 0.05 or more and 0.25 or less, more preferably 0.10 or more and 0.20 or less.

The atomic ratio (proportion) may be determined through composition analysis by energy dispersive X-ray spectroscopy (EDX).

Other specific examples of the material for forming the piezoelectric film include PMN-PT (Pb(Mg_{1/3}Nb_{2/3}) O₃—PbTiO₃), barium titanate (BaTiO₃), lead titanate (PbTiO₃), lead metaniobate (PbNb₂O₆), bismuth titanate (Bi₄Ti₃O₁₂), KNN ((K_{0.5}Na_{0.5}) NbO₃), KNN-LN (((K_{0.5}Na_{0.5}) NbO₃)—LiNbO₃), and BT-BNT-BKT ((Bi_{0.5}Na_{0.5}) TiO₃—(Bi_{0.5}K_{0.5}) TiO₃—BaTiO₃).

The thickness of the piezoelectric film is, for example, more than 0.2 μm, preferably 0.3 μm or more, more preferably 1 μm or more, still more preferably 3 μm or more. In one embodiment, the thickness of the piezoelectric film may be 5 μm or more or 6 μm or more. With such thickness, for example, a low-voltage-driven actuator with high displacement can be obtained. For example, when the piezoelectric film is formed by film formation such as sputtering, it is difficult to achieve such thickness in view of the film stress of the piezoelectric film to be obtained, productivity, and the like. In contrast, when the piezoelectric film includes a non-oriented polycrystalline substance, the piezoelectric film can be set to such thickness. In addition, when the piezoelectric film includes a non-oriented polycrystalline substance, a composite substrate in which the occurrence of a warp is suppressed can be obtained even with such thickness. Meanwhile, the thickness of the piezoelectric film is, for example, 200 μm or less, preferably 150 μm or less, more preferably 100 μm or less, still more preferably 50 μm or less, particularly preferably 20 μm or less. With such thickness, defects caused by a difference in thermal expansion from the support substrate (e.g., occurrence of cracking caused by heating) can be suppressed, and for example, a heating process (e.g., 100° C. or more) in the production of a piezoelectric device can be supported. Specifically, mask formation using photolithography or the like in the production of a MEMS device can be supported.

As described above, the piezoelectric film may include a sintered body. The sintered body may be formed by any appropriate method. In one embodiment, the sintered body may be formed by subjecting raw material powder to pressure sintering. As a specific example, the sintered body may be formed by subjecting raw material powder mixed at a predetermined blending ratio or powder obtained by calcining raw material powder mixed at a predetermined blending ratio and then pulverizing the resultant to a predetermined particle diameter (e.g., from 0.1 μm to 10 μm) to pressure sintering. Any appropriate method may be adopted as the pressure sintering. Specifically, a HIP method, a hot press method, or the like may be adopted.

The piezoelectric film may be obtained, for example, by subjecting the sintered body (piezoelectric substrate) to processing, such as grinding or polishing, to a desired thickness. In the formation of the piezoelectric film, polarization treatment is performed at any appropriate timing. In one embodiment, a pair of electrodes are respectively arranged on facing surfaces of a sintered body (piezoelectric substrate) formed in a plate shape, and polarization treatment is performed by an electric field in a direction from one electrode to the other electrode. After that, the resultant is subjected to the processing, such as grinding or polishing, to thereby provide a piezoelectric film.

The arithmetic average roughness Ra of the piezoelectric film is preferably 2 nm or less, more preferably 1 nm or less, still more preferably 0.3 nm or less.

### A-2. Support Substrate

Any appropriate substrate may be used as the support substrate. The support substrate may include a single crystalline substance, or may include a polycrystalline substance. In addition, the support substrate may include a metal. A material for forming the support substrate is preferably selected from the group consisting of: silicon; sialon; sapphire; cordierite; mullite; glass; quartz; crystal; alumina; SUS; an iron-nickel alloy (42 alloy); and brass.

The silicon may be single crystalline silicon, polycrystalline silicon, or high resistance silicon. The support substrate may be silicon on insulator (SOI).

Typically, the sialon is a ceramic obtained by sintering a mixture of silicon nitride and alumina, and has composition represented by, for example, Si_{6-w}Al_{w}O_{w}N_{8-w}. Specifically, the sialon has such composition that alumina is mixed into silicon nitride, and “w” in the formula represents the mixing ratio of alumina. “w” preferably represents 0.5 or more and 4.0 or less.

Typically, the sapphire is a single crystalline material having the composition of Al₂O₃, and the alumina is a polycrystalline material having the composition of Al₂O₃. The alumina is preferably translucent alumina.

Typically, the cordierite is a ceramic having the composition of 2MgO·2Al₂O₃·5SiO₂, and the mullite is a ceramic having composition in the range of from 3Al₂O₃·2SiO₂ to 2Al₂O₃·SiO₂.

Any appropriate thickness may be adopted as the thickness of the support substrate. The thickness of the support substrate is, for example, from 100 μm to 1,000 μm.

### A-3. Joining Layer

A material for forming the joining layer, which may be incorporated into the composite substrate, is, for example, silicon, tantalum oxide, niobium oxide, aluminum oxide, titanium oxide, or hafnium oxide. The thickness of the joining layer is, for example, from 5 nm to 1 μm, preferably from 10 nm to 200 nm.

The joining layer typically includes an amorphous substance. Specifically, the joining layer may be an amorphous layer. When the joining layer includes an amorphous substance, for example, the polishing described later is easily performed, and a preferred surface roughness is easily obtained on a joining surface.

The joining layer may be formed by any appropriate method. The joining layer may be formed by, for example, physical deposition, such as sputtering, vacuum deposition, or ion beam assisted deposition (IAD), chemical deposition, or an atomic layer deposition (ALD) method. The formation of the joining layer may be performed at, for example, from room temperature (25° C.) to 300° C.

### A-4. Electrode

In the illustrated example, the electrode (lower electrode) has a laminated structure including the first lower electrode layer, the second lower electrode layer, and the third lower electrode layer. The first lower electrode layer and the third lower electrode layer, which are brought into contact with the layers adjacent to the electrode, may each function as an adhesion layer. For example, a metal, such as Ti, Cr, Ni, Mo, or Al, is used as a material for forming each of the first lower electrode layer and the third lower electrode layer. Those metals may be used alone or in combination thereof.

In one embodiment, the material for forming the first lower electrode layer and the material for forming the third lower electrode layer are substantially identical to each other. Specifically, the first lower electrode layer and the third lower electrode layer have substantially the same composition. For example, the first lower electrode layer includes a metal (e.g., Ti), and the third lower electrode layer includes a metal (e.g., Ti). Such configuration can be adopted when the piezoelectric film includes a non-oriented polycrystalline substance. For example, when the piezoelectric film is formed by film formation, the adjacent layer (electrode) functions as a seed crystal layer for the piezoelectric film and includes a material having predetermined physical properties (e.g., a lattice constant). In contrast, when the piezoelectric film includes a non-oriented polycrystalline substance, options for the material for forming the adjacent layer (electrode) are increased, and a material may be selected, for example, from the viewpoints of production efficiency, the characteristics of a composite substrate (piezoelectric element) to be obtained, and the like.

The thickness of each of the first lower electrode layer and the third lower electrode layer, which may function as adhesion layers with the adjacent layers, is, for example, 1 nm or more and 100 nm or less, preferably 3 nm or more and 50 nm or less, more preferably 5 nm or more and 20 nm or less.

A metal, such as Pt or Au, is preferably used as a material for forming the second lower electrode layer. The thickness of the second lower electrode layer is, for example, 10 nm or more and 1,000 nm or less, preferably 50 nm or more and 250 nm or less.

The electrode (second lower electrode layer) typically includes an amorphous substance. Such configuration may contribute to, for example, the suppression of a warp that occurs in a composite substrate to be obtained.

The electrode may be formed by any appropriate method. For example, the electrode may be formed by, for example, physical vapor deposition, such as sputtering, vacuum deposition, or ion beam assisted deposition (IAD). In one embodiment, the first lower electrode layer and the third lower electrode layer may be formed by sputtering under the same conditions through use of the same target (e.g., a Ti target). The formation of the electrode may be performed at, for example, from room temperature (25° C.) to 300° C.

### A-5. Production Method

The above-mentioned composite substrate may be obtained, for example, by joining (directly joining) the above-mentioned piezoelectric film or piezoelectric substrate and the above-mentioned support substrate to each other.

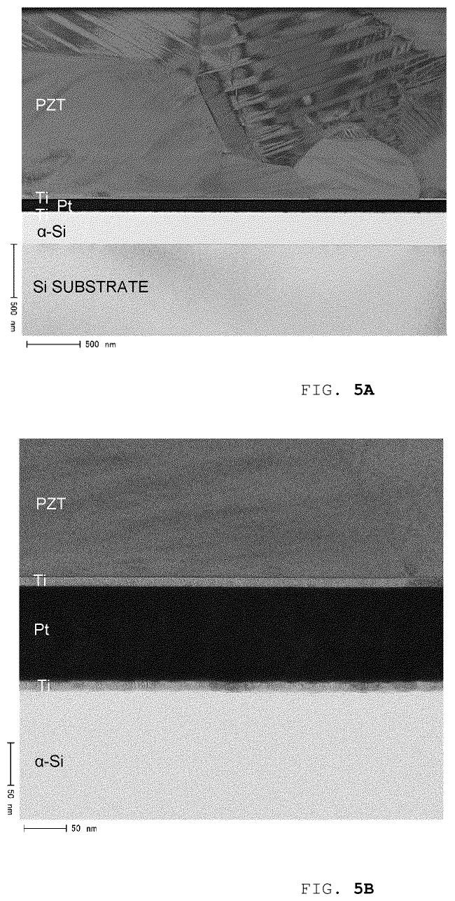

FIG. 4A to FIG. 4C are each a view for illustrating an example of a production process for a composite substrate according to one embodiment. FIG. 4A is an illustration of a state in which the formation of the electrode 30 and the joining layer 20 on a piezoelectric substrate 42 is completed. The piezoelectric substrate 42 has a first main surface 42a and a second main surface 42b facing each other. The first lower electrode layer 31, the second lower electrode layer 32, and the third lower electrode layer 33 are sequentially formed on the first main surface 42a side to form the electrode 30, and then the joining layer 20 is formed.

FIG. 4B is an illustration of the step of directly joining the piezoelectric substrate 42 having the electrode 30 and the joining layer 20 formed thereon and the support substrate 10 to each other. At the time of the direct joining, the joining surfaces of the layer and the substrate are preferably activated by any appropriate activation treatment. The direct joining is performed by, for example, activating a surface 20a of the joining layer 20, activating a surface 10a of the support substrate 10, then bringing the activated surface of the joining layer 20 and the activated surface of the support substrate 10 into contact with each other, and pressurizing the resultant. Thus, a composite substrate 102 illustrated in FIG. 4C is obtained.

In one embodiment, an end portion of the joining layer 20 on the activated surface side and/or an end portion of the support substrate 10 on the activated surface side contains an element (e.g., argon) for forming a gas to be used in the activation treatment. Specifically, the end portion of the joining layer 20 and/or the support substrate 10 on the activated surface side is turned into an amorphous region (region containing an amorphous substance) containing an element for forming a gas to be used in the activation treatment. The thickness of such amorphous region is, for example, from 2 nm to 30 nm. The argon concentration of the amorphous region is, for example, from 0.5 atm % to 30 atm %. Although the distribution state of argon in the amorphous region is not particularly limited, for example, in the amorphous region, the argon concentration is increased toward the activated surface side.

The second main surface 42b of the piezoelectric substrate 42 of the resultant composite substrate 102 is typically subjected to processing, such as grinding or polishing, so that a piezoelectric film having the above-mentioned desired thickness is obtained. In one embodiment, the processing, such as grinding or polishing, is performed so that the thickness of a piezoelectric film to be obtained is more than 0.2 μm. According to such form, the grain boundary binding force of a piezoelectric film to be obtained and the binding force with the support substrate are not weakened by the processing load, and the shedding of crystals for forming the piezoelectric film and the occurrence of peeling of the piezoelectric film can be suppressed.

The surface of each layer (specifically, the piezoelectric film or the piezoelectric substrate, the support substrate, or the joining layer) is preferably a flat surface. Specifically, the arithmetic average roughness Ra of the surface of each layer is, for example, 5 nm or less, preferably 2 nm or less, more preferably 1 nm or less, still more preferably 0.3 nm or less. A method of flattening the surface of each layer is, for example, mirror polishing through chemical-mechanical polishing (CMP) or lap polishing.

At the time of the film formation and the joining described above, the surface of each layer is preferably washed for, for example, removing the residue of a polishing agent. A method for the washing is, for example, wet washing, dry washing, or scrub washing. Of those, scrub washing is preferred because the surface can be simply and efficiently washed. A specific example of the scrub washing is a method including washing the surface in a scrub washing machine with a detergent (e.g., a SUNWASH series manufactured by Lion Corporation) and then with a solvent (e.g., a mixed solution of acetone and isopropyl alcohol (IPA)).

The activation treatment is typically performed by irradiating the joining surface with a neutralized beam. The activation treatment is preferably performed by generating the neutralized beam with an apparatus such as an apparatus described in JP 2014-086400 A, and irradiating the joining surface with the beam. Specifically, a saddle-field fast atomic beam source is used as a beam source, and an inert gas, such as argon or nitrogen, is introduced into the chamber of the apparatus, followed by the application of a high voltage from the DC power source thereof to an electrode thereof. Thus, a saddle-field electric field is generated between the electrode (positive electrode) and the casing (negative electrode) thereof to cause electron motion, to thereby generate the beams of an atom and an ion by the inert gas. Of the beams that have reached the grid of the fast atomic beam source, an ion beam is neutralized by the grid, and hence the beam of a neutral atom is emitted from the fast atomic beam source. The voltage at the time of the activation treatment by the beam irradiation is preferably set to from 0.5 kV to 2.0 kV, and a current at the time of the activation treatment by the beam irradiation is preferably set to from 50 mA to 200 mA.

The joining surfaces are preferably brought into contact with each other and pressurized in a vacuum atmosphere. A temperature at this time is typically normal temperature. Specifically, the temperature is preferably 20° C. or more and 40° C. or less, more preferably 25° C. or more and 30° C. or less. A pressure to be applied is preferably from 100 N to 20,000 N.

In the illustrated example, the composite substrate is obtained by joining the piezoelectric substrate having the electrode and the joining layer formed thereon and the support substrate to each other, but the present invention is not limited to such form. For example, the support substrate and the piezoelectric substrate (piezoelectric film) may be joined to each other after the layers (e.g., the electrode and the joining layer) that may be arranged between the piezoelectric film and the support substrate have been arranged on the support substrate side. Specifically, the composite substrate may include an argon-containing amorphous layer, which is located between the piezoelectric film and the support substrate, and which contains argon. The argon-containing amorphous layer may correspond to the above-mentioned amorphous region.

### EXAMPLES

The present invention is specifically described below by way of Examples. However, the present invention is not limited by these Examples. Unless otherwise stated, the following procedure was performed at room temperature.

### Example 1

PbZrO₃ powder, PbTiO₃ powder, Nb₂O₅ powder, and ZnO powder were mixed under stirring in a ball mill through use of water as a dispersion material, and the resultant mixture was dried, and was calcined (at 900° C. for 2 hours) in the atmosphere. After that, the resultant was subjected to wet pulverization in the ball mill again for 20 hours to provide powder having a particle diameter of about 1 μm. Then, the powder was subjected to press forming to provide a compact.

The resultant compact was subjected to preliminary firing at 1,250° C. for 2 hours in the atmosphere. After the firing, the resultant was cooled in the atmosphere to provide a preliminary fired body. The resultant preliminary fired body was embedded in a container filled with mixed powder of PbO and Zro₂, and the top of the container was covered with a lid. The container was placed in an internal heating high-temperature and high-pressure furnace, and a temperature in the furnace was increased from room temperature to 1,100° C. over 4.5 hours. Thus, hot isostatic pressing treatment (HIP method) was performed. Specifically, the hot isostatic pressing treatment was performed as follows: at the time of the increase in temperature, a pressure was applied up to 280 bar at 1,000° C., and the pressure was increased from 280 bar to 600 bar in 1 hour from the time point when the temperature exceeded 1,000° C., and the resultant was kept at 1, 100° C. and 600 bar for 1 hour. Thus, a plate-shaped sintered body was obtained.

An electrode was formed on each of the upper surface and the lower surface of the resultant sintered body, and the sintered body was subjected to polarization treatment through application of a predetermined voltage. After that, the sintered body was subjected to beveling, grinding, and lap polishing processing to provide a wafer (piezoelectric substrate) having a first surface and a second surface facing each other, and having a diameter of 4 inches and a thickness of 500 μm. The degree of c-axis orientation of the resultant piezoelectric substrate was determined to be 2% by the Lotgering method. The degree of c-axis orientation is a degree of (001) plane orientation F₍₀₀₁₎ calculated through use of the following expressions from an XRD profile measured with an XRD apparatus when the surface (orientation surface) of the piezoelectric substrate was irradiated with an X-ray. The evaluation was performed in the range of a diffraction angle 2θ of from 10° to 80°.

$${F}_{( 001 )} = ( p - {p}_{0} ) / ( 1 - {p}_{0} ) \times 100$$

$$p = \sum I ( 001 ) / \sum I ( hk 1 )$$

$${p}_{0} = \sum {I}_{0} ( 001 ) / \sum {I}_{0} ( hk 1 )$$

(I and I₀ each represent a diffraction intensity, and “p” and p₀ are each calculated from the ratio of diffraction intensities derived from a c-axis diffraction plane (001) to diffraction intensities of all diffraction planes (hkl). I and “p” each represent a value obtained from an XRD profile when the surface (orientation surface) of the piezoelectric substrate is irradiated with an X-ray, and I₀ and p₀ each represent a value obtained from an XRD profile when a sample obtained by powderizing the piezoelectric substrate is measured.)

The first surface of the resultant piezoelectric substrate was subjected to finishing by chemical-mechanical polishing (CMP) to be mirror-finished so that the arithmetic average roughness Ra was less than 2 nm. Herein, the arithmetic average roughness Ra is a value measured with an atomic force microscope (AFM) in a field of view measuring 10 μm by 10 μm.

A Ti film having a thickness of 10 nm, a Pt film having a thickness of 100 nm, a Ti film having a thickness of 10 nm, and a silicon film having a thickness of 150 nm were formed on the mirror-finished first surface of the piezoelectric substrate by sputtering in the stated order. After that, the surface of the silicon film was subjected to chemical-mechanical polishing (CMP) to achieve an arithmetic average roughness Ra of 0.2 nm.

A silicon substrate including an orientation flat portion, and having a diameter of 4 inches and a thickness of 500 μm was prepared. The surface of the silicon substrate is subjected to chemical-mechanical polishing (CMP), and has an arithmetic average roughness Ra of 0.2 nm.

Next, the piezoelectric substrate and the support substrate were directly joined to each other. Specifically, the surface (silicon film side) of the piezoelectric substrate and the surface of the silicon substrate were washed, and then both the substrates were loaded into a vacuum chamber, followed by its evacuation to a vacuum of the order of 10-6 Pa. After that, the surfaces of both the substrates were irradiated with fast atomic beams (acceleration voltage: 1 kV, Ar flow rate: 27 sccm) for 120 seconds. After the irradiation, the beam-irradiated surfaces of both the substrates were superimposed on each other, and both the substrates were joined to each other by being pressurized at 10,000 N for 2 minutes to provide a joined body.

Then, the second surface of the piezoelectric substrate of the resultant joined body was subjected to grinding and polishing. Thus, a composite substrate including a piezoelectric film having a thickness of 0.3 μm was obtained.

### Examples 2 to 6

Composite substrates were each obtained in the same manner as in Example 1 except that the conditions for the grinding and polishing of the second surface of the piezoelectric substrate were changed.

### Example 7

A composite substrate was obtained in the same manner as in Example 4 except that a Au film having a thickness of 100 nm was formed by sputtering instead of forming the Pt film having a thickness of 100 nm.

### Example 8

A composite substrate was obtained in the same manner as in Example 4 except that the Ti film and the Pt film were not formed by sputtering.

### Example 9

A composite substrate was obtained in the same manner as in Example 4 except that a piezoelectric substrate having a degree of c-axis orientation of 9% as determined by the Lotgering method was used.

### Example 10

A composite substrate was obtained in the same manner as in Example 4 except that a piezoelectric substrate having a degree of c-axis orientation of 58% as determined by the Lotgering method was used.

### Example 11

A composite substrate was obtained in the same manner as in Example 4 except that a piezoelectric substrate having a degree of c-axis orientation of 79% as determined by the Lotgering method was used.

### <TEM Observation>

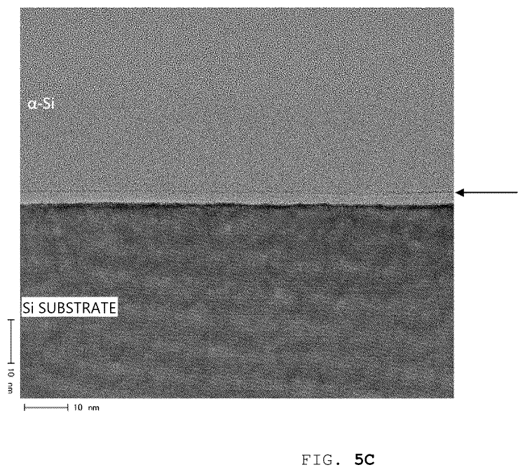

Transmission electron microscope (TEM) observation (magnification: 50,000, 400,000, and 2,000,000) of a cross-section of the composite substrate of Example 4 was performed. Observation photographs are shown in FIG. 5A, FIG. 5B, and FIG. 5C. In the cross-sectional TEM observation, a sample for observation was prepared from the resultant composite substrate by a FIB method.

### <EDX Analysis>

The EDX analysis of the cross-section of the composite substrate of Example 4 revealed that the argon concentration in a layer (amorphous region formed by the activation treatment) indicated by the arrow in FIG. 5C was 3.0 atm %.

### Comparative Example 1

A silicon substrate including an orientation flat portion, having a first surface and a second surface facing each other, and having a diameter of 4 inches, a thickness of 500 μm, and a plane orientation of (100) was prepared.

Then, while the silicon substrate was heated to 560° C., a Ti film having a thickness of 10 nm, a Pt film having a thickness of 100 nm, and a strontium ruthenate (SRO) film having a thickness of 10 nm were formed on the first surface by sputtering in the stated order. At that time, the resultant SRO film was crystallized and oriented to a (100) plane through the film formation by heating at 560° C.

Subsequently, while the silicon substrate was heated to 560° C., a PZT film (piezoelectric film) having a thickness of 3 μm was formed on the SRO film by sputtering through use of a sintered body (0.8PbZr_{0.53}Ti_{0.47}O₃+0.2PbO) mixed with 20 mol % excess PbO as a target. Specifically, a PZT film that was crystallized and oriented to a (001) plane was obtained through the film formation by heating at 560° C.

Thus, a composite substrate was obtained. The degree of c-axis orientation of the resultant piezoelectric film was determined to be 89% by the Lotgering method.

### Comparative Example 2

A composite substrate was obtained in the same manner as in Comparative Example 1 except that the thickness of the PZT film was changed to 5 μm.

### Comparative Example 3

An attempt was made to form a PZT film so that the thickness thereof was 6 μm. However, the silicon substrate was fractured owing to a warp that occurred at the time of film formation, and hence a composite substrate was not able to be obtained.

The composite substrates of Examples and Comparative Examples were evaluated as described below. The evaluation results are summarized in Table 1.

### <Evaluation 1>

A warp of a composite substrate (wafer) was measured with a laser displacement meter (“LK-G5000” manufactured by Keyence Corporation). Specifically, the thickness (height) distribution of the wafer when the wafer was placed on a movable stage with the silicon substrate facing the placement surface was measured. The measurement was performed with respect to two lines in a horizontal direction and a vertical direction with respect to an orientation flat of the wafer, and a larger measured value is shown in Table 1.

### <Evaluation 2-1>

The composite substrates (wafers) of Examples 1 to 7 and 9 to 11 were each cut to a size of 30 mm×5 mm, and a Pt film having a thickness of 100 nm was formed by sputtering in the range of 20 mm×5 mm of the surface of the piezoelectric film. Thus, a cantilever was produced.

The composite substrates (wafers) of Comparative Examples 1 and 2 were each cut to a size of 30 mm×5 mm, and a SRO film having a thickness of 10 nm and a Pt film having a thickness of 100 nm were formed by sputtering (an amorphous film was formed without heating) in the range of 20 mm×5 mm of the surface of the piezoelectric film. After that, polarization treatment was performed through application of a predetermined voltage. Thus, a cantilever was produced.

A voltage (at 500 Hz) was applied to the upper electrode (Pt film) and the lower electrode (Pt film or Au film) of the resultant cantilever so that the electric field intensity applied to the piezoelectric film was 0.34 kV/mm, to thereby drive the element.

The amount of amplitude (amount of displacement) at a distal end of the cantilever was measured with a laser Doppler vibrometer, and d31 was calculated by the following formula.

$$Calculating formula of Piezoelectric coefficient {d}_{31} \qquad [ Math . 1 ]$$

$$- d 31 ≃ \frac{{( h \text{?} )}^{2} \cdot {S}_{11}^{p}}{3 \cdot S {\text{?}}_{11} \cdot {L}^{2} \cdot V} δ$$

$$1. \text{?} et al . / Sensors and Actuators A 107 ( \text{?} ) \text{?} - 74$$

$$h \text{?} : Thickness of silicon cantilever$$

$${S}_{11}^{2} : Elastic compliance of PZT film \to 1 / ( 70 \times 10 \text{?} Pa ) assumed value$$

$$S {\text{?}}_{11} : Elastic compliance of silicon \to 1 / ( \text{?} * 10 \text{?} Pa )$$

$$L : Length of silicon cantilever$$

$$V : Applied voltage$$

$$δ : Displacement of cantilever$$

$$\text{?} \text{indicates text missing or illegible when filed}$$

### <Evaluation 2-2>

After the silicon substrate and silicon film of the composite substrate (wafer) of Example 8 had been removed by etching, Pt films (upper electrode and lower electrode) each having a thickness of 100 nm were respectively formed by sputtering on an upper surface of the piezoelectric film and a lower surface exposed by etching to provide a laminate. After that, the laminate was diced to a size of 20 mm×2 mm.

The thickness (height) of the resultant chip was measured with a laser displacement meter.

After a DC voltage had been applied to the upper electrode and the lower electrode so that the electric field intensity applied to the piezoelectric film was 0.34 kV/mm, the thickness of the chip was measured with a laser displacement meter.

d31 was calculated from the amount of displacement before and after the voltage application.

TABLE 1

| | | | Thickness of | Warp of | |
|---|---|---|---|---|---|
| | Configuration | F₍₀₀₁₎ | piezoelectric | wafer | d31 |
| | of electrode | (%) | film (μm) | (μm) | (pC/N) |
| Example 1 | Ti/Pt/Ti | 2 | 0.3 | 6 | 189 |
| Example 2 | Ti/Pt/Ti | 2 | 3 | 15 | 192 |
| Example 3 | Ti/Pt/Ti | 2 | 5 | 20 | 195 |
| Example 4 | Ti/Pt/Ti | 2 | 10 | 35 | 196 |
| Example 5 | Ti/Pt/Ti | 2 | 20 | 45 | 235 |
| Example 6 | Ti/Pt/Ti | 2 | 100 | 51 | 240 |
| Example 7 | Ti/Au/Ti | 2 | 10 | 25 | 203 |
| Example 8 | — | 2 | 10 | 17 | 201 |
| Example 9 | Ti/Pt/Ti | 9 | 10 | 38 | 189 |
| Example 10 | Ti/Pt/Ti | 58 | 10 | 41 | 175 |
| Example 11 | Ti/Pt/Ti | 79 | 10 | 42 | 172 |
| Comparative | SRO/Pt | 89 | 3 | 137 | 100 |
| Example 1 | | | | | |
| Comparative | SRO/Pt | 89 | 5 | 228 | 105 |
| Example 2 | | | | | |

In each of Examples, the occurrence of a warp is suppressed. In addition, in each of Examples, excellent piezoelectric characteristics are recognized. Specifically, excellent piezoelectric characteristics are recognized also in a low electric field region (e.g., <5 kV/mm).

It is conceived that, in Comparative Examples 1 and 2, through adjustment of the heating temperature, the film formation output, the kind of an additive gas in a chamber, the thickness of each layer, and the like at the time of the sputtering film formation, for example, the compressive stress and the tensile stress of each layer can be balanced to reduce a warp. However, it is conceived that, even when the warp is reduced, a residual stress still remains, for example, the piezoelectric constant and reliability are low, and hence the composite substrates of Comparative Examples 1 and 2 are not each suitable for use as a piezoelectric element used in a piezoelectric actuator.

### <Temperature Characteristics>

The temperature characteristics of the composite substrates of Example 4 and Comparative Example 1 were evaluated.

Specifically, in the above-mentioned evaluation 2-1, the cantilever was placed on a hot plate and heated from room temperature (25° C.) to 120° C. Then, a voltage (at 500 Hz) was applied so that the electric field intensity applied to the piezoelectric film was 1 kV/mm (electric field intensity/coercive electric field=1.0) in Example 4 and 5 kV/mm (electric field intensity/coercive electric field=0.75) in Comparative Example 1 to drive the element. Thus, the amount of displacement was measured. The temperature was measured by placing a thermocouple in the vicinity of the cantilever.

The change rate of the amount of displacement (ratio of the amount of displacement at: 120° C. to the amount of displacement at room temperature) was 1.11 in Example 4 and 1.36 in Comparative Example 1. It can be said that the temperature stability is excellent in Example 4.

### <Reliability>

The reliability was evaluated for the composite substrate of Example 4. Specifically, in the above-mentioned evaluation 2-1, the cantilever was placed on a hot plate and heated from room temperature (25° C.) to 120° C. Then, a voltage (at 500 Hz) was applied so that the electric field intensity applied to the piezoelectric film was 1 kV/mm (electric field intensity/coercive electric field=1.0) to drive the element. Thus, a change in amount of displacement and an increase in temperature of the element by heat generation of the element were measured for 7 days.

The change rate of the amount of displacement after 7 days as compared to that at the time of start of measurement was 0.98. In addition, the element did not generate heat, and the temperature of the element after 7 days was 120° C. It can be said that the composite substrate of Example is excellent in reliability, including the fact that an organic (e.g., epoxy-based or acrylic) adhesive is not used.

### <TTV>

A TTV was measured for the composite substrate of Example 4. Specifically, an outer periphery of the resultant composite substrate (4 inches) was cut by about 0.5 mm, and a TTV was measured with FlatMaster 200 manufactured by Tropel Corporation in the range of 499 mm. As a result, the TTV of the composite substrate of Example 4 was 1.6 μm.

### <Thickness Distribution of Piezoelectric Film>

The thickness distribution of the piezoelectric film was evaluated for each of the composite substrates of Example 2 and Comparative Example 1. Specifically, an outer periphery of the resultant composite substrate (4 inches) was cut by about 5 mm, and thicknesses at 17 points in a plane were measured with a microspectroscopic thickness meter (“OPTM-A2” manufactured by Otsuka Electronics Co., Ltd.) in the range of φ90 mm.

The thickness distribution (variation) was 3±0.05 μm (±1.7%) in Example 2 and 3±0.15 μm (±5.0%) in Comparative Example 1. It can be said that the thickness variation is small in Example 2. Also in other Examples different in thickness of the piezoelectric film, processing (grinding and polishing) can be performed to the same degree (accuracy of +0.05 μm) as that in Example 2, and the ratio of variation to the thickness of the piezoelectric film is reduced when the thickness of the piezoelectric film is increased.

When a high-performance sputtering film forming apparatus is used for forming the piezoelectric film, the thickness variation can be suppressed to from +2% to +3%, but the result of Example 2 (±1.7%) is not obtained. In addition, it is difficult to polish the formed piezoelectric film.

### INDUSTRIAL APPLICABILITY

The composite substrate according to the embodiment of the present invention can be suitably used in a piezoelectric element. The piezoelectric element is used in a piezoelectric device, such as an ink jet head, a MEMS mirror device, a gyroscope sensor, an ultrasonic sensor, a pyroelectric infrared sensor, or a haptic sensor (haptic).

What is claimed is:

1. A composite substrate, comprising:
a support substrate;
a piezoelectric film arranged above the support substrate; and
a joining layer arranged between the support substrate and the piezoelectric film,
wherein the piezoelectric film includes a polycrystalline substance having a degree of c-axis orientation determined by a Lotgering method of 80% or less, and
wherein the joining layer includes an amorphous substance.

2. The composite substrate according to claim 1, wherein the piezoelectric film contains a PZT-based compound.

3. The composite substrate according to claim 1, wherein the piezoelectric film contains a ternary PZT.

4. The composite substrate according to claim 1, wherein the piezoelectric film includes a sintered body.

5. The composite substrate according to claim 1, wherein the piezoelectric film has a thickness of 0.3 μm or more and 100 μm or less.

6. The composite substrate according to claim 1, further comprising an electrode arranged between the piezoelectric film and the support substrate,
wherein the electrode includes a first electrode layer, a second electrode layer, and a third electrode layer, and
wherein a material for forming the first electrode layer and a material for forming the third electrode layer are substantially identical to each other.

7. The composite substrate according to claim 1, further comprising an electrode arranged between the piezoelectric film and the support substrate,
wherein the electrode includes an amorphous substance.

8. The composite substrate according to claim 1, further comprising an argon-containing amorphous layer, which is arranged between the piezoelectric film and the support substrate, and which contains argon.

9. The composite substrate according to claim 1,
wherein the support substrate has an amorphous region formed in an end portion thereof on an upper side, and
wherein the amorphous region has a thickness of from 2 nm to 30 nm.

10. The composite substrate according to claim 9,
wherein the amorphous region contains argon, and
wherein the amorphous region has an argon concentration of from 0.5 atm % to 30 atm %.

11. The composite substrate according to claim 1, wherein the composite substrate has a total thickness variation of 10 μm or less.

12. A piezoelectric device, comprising the composite substrate of claim 1.

13. A method of producing a composite substrate, comprising:
preparing a piezoelectric substrate including a sintered body; and
joining the piezoelectric substrate and a support substrate to each other via a joining layer including an amorphous substance.

14. The method of producing a composite substrate according to claim 13, further comprising forming the joining layer on the piezoelectric substrate at 300° ° C. or less.

15. The method of producing a composite substrate according to claim 13, further comprising forming an electrode on the piezoelectric substrate at 300° C. or less.
